(19) United States
(12) Patent Application Publication
(10) Pub. No.: US 2012/0169340 A1
(43) Pub. Date: Jul. 5, 2012

(54) MR IMAGING SYSTEM WITH FREELY ACCESSIBLE EXAMINATION VOLUME

(75) Inventors: Christoph Leussler, Hamburg (DE); Daniel Wirtz, Hamburg (DE)

(73) Assignee: KONINKLIJKE PHILIPS ELECTRONICS N.V., EINDHOVEN (NL)

(21) Appl. No.: 13/394,969

(22) PCT Filed: Sep. 14, 2010
(86) PCT No.: PCT/IB2010/054136

§ 371 Date: Mar. 8, 2012

(30) Foreign Application Priority Data
Sep. 28, 2009 (EP) 09171488.1
Jan. 28, 2010 (EP) 10151987.4

(51) Int. Cl. G01R 33/48; G01R 33/32

(52) U.S. Cl. 324/309; 324/318

(57) ABSTRACT

The invention relates to a magnetic resonance imaging system (1) comprising: a main magnet for generating a uniform, steady magnetic field within an examination volume (21), an RF waveguide (19) for guiding travelling RF waves along an axis of the examination volume (21) in at least one travelling mode of the RF waveguide (19), at least one RF antenna (9) for transmitting RF pulses to and/or receiving MR signals from a body (10) of a patient positioned in the examination volume (21), wherein the RF antenna (9) is configured to couple to the at least one travelling mode of the RF waveguide (19), and wherein the RF antenna (9) is located on the imaging system such that the examination volume (21) is freely accessible, a control unit (15) for controlling the temporal succession of RF pulses, and a reconstruction unit (17) for reconstructing an MR image from the received MR signals. Further, the invention relates to an RF antenna (9) for an MR imaging system (1), wherein the RF antenna (9) is formed by an electrically conductive plate (22) comprising at least one recess (23).

### FIELD OF THE INVENTION

The invention relates to the field of magnetic resonance (MR) imaging. It concerns an MR imaging system comprising an RF waveguide for guiding traveling RF waves and at least one RF antenna configured to couple to at least one traveling mode of the RF waveguide. Further, the invention relates in general to an RF antenna for an MR system.

### BACKGROUND OF THE INVENTION

Image forming MR methods which utilize the interaction between magnetic field and nuclear spins in order to form two-dimensional or three-dimensional images are widely used nowadays, notably in the field of medical diagnostics, because for the imaging of soft tissue they are superior to other imaging methods in many respects, and do not require ionizing radiation and are usually not invasive.

According to the MR method in general, the body of the patient to be examined is arranged in a strong, uniform magnetic field whose direction at the same time defines an axis (normally the z-axis) of the coordinate system on which the measurement is based. The magnetic field produces different energy levels for the individual nuclear spins in dependence on the applied magnetic field strength which spins can be excited (spin resonance) by application of an alternating electromagnetic field (RF field) of defined frequency, the so called Larmor frequency or MR frequency. From a macroscopic point of view the distribution of the individual nuclear spins produces an overall magnetization which can be deflected out of the state of equilibrium by application of an electromagnetic pulse of appropriate frequency (RF pulse) while the magnetic field extends perpendicularly to the z-axis, so that the magnetization performs a precessional motion about the z-axis.

The variation of the magnetization can be detected by means of receiving RF antennas which are arranged and oriented within an examination volume of the MR device in such a manner that the variation of the magnetization is measured in the direction perpendicular to the z-axis.

In order to realize spatial resolution in the body, linear magnetic field gradients extending along the three main axes are superposed on the uniform magnetic field, leading to a linear spatial dependency of the spin resonance frequency. The signal picked up in the receiving antennas then contains components of different frequencies which can be associated with different locations in the body. The signal data obtained via the receiving antennas corresponds to the spatial frequency domain and is called k-space data. The k-space data usually includes multiple lines acquired with different phase encoding. Each line is digitized by collecting a number of samples. A set of k-space data is converted to an MR image, e.g. by means of Fourier transformation.

In recent years, two strong trends are observable in the design of MR imaging systems: on the one hand the clinical need and clinical acceptance of MR imaging systems operating at high magnetic field strength (three or more Tesla) became obvious. On the other hand, the dimensions of the examining volume (the inner bore diameter) of MR systems are steadily increasing.

Brunner et al (Nature, Volume 457, 2009, pages 994-998) have proposed a traveling wave approach for high field MR imaging. The examined patient is positioned within an RF waveguide that is used for guiding traveling RF waves along the longitudinal bore axis in at least one traveling mode of the RF waveguide. The traveling RF waves propagate through the examination volume of the MR imaging apparatus and are used for exciting and detecting magnetic resonance. The essential advantages of this concept are that it enables an excellent RF coverage as well as a high degree of RF homogeneity throughout the examination volume. For this reason, traveling wave MR imaging has the potential to facilitate the simultaneous exploration of the highest field strengths and larger bore diameters available for medical MR imaging.

However, MR imaging using such traveling waves requires a new type of RF antennas. Instead of coupling to the near field of the examined body, a traveling wave antenna must couple to the traveling modes of the RF waveguide. In the known approach, a circularly polarized patch antenna is used which is positioned at the open end of the cylindrical bore of the MR imaging apparatus. A problem of this setup is that it disables open access to the inner bore. This is critical for patient monitoring and patient accessibility which both are particularly important in MR imaging and MR guided medical interventions.

From the forgoing it is readily appreciated that there is a need for an improved MR imaging system. It is consequently an object of the invention to provide an MR imaging system having a large and easily accessible inner bore. Moreover, the MR imaging system shall enable high quality MR imaging at a high main magnetic field strength.

### SUMMARY OF THE INVENTION

In accordance with the present invention, an MR imaging system is disclosed which comprises a main magnet for generating a uniform, steady magnetic field within an examination volume. The MR system further comprises an RF waveguide for guiding traveling RF waves along an axis of the examination volume in at least one traveling mode of the RF waveguide. Further, the system comprises at least one RF antenna for transmitting RF pulses to and/or receiving MR signals from a body of a patient positioned in the examination volume, wherein the RF antenna is configured to couple to the at least one traveling mode of the RF waveguide, wherein the RF antenna is located on the imaging system such that the examination volume is freely accessible, i.e. the inner bore of the magnet comprising the examination volume is open accessible. Further, the system comprises a control unit for controlling the temporal succession of RF pulses and a reconstruction unit for reconstructing an MR image from the received MR signals.

This MR imaging system uses the above described traveling wave concept. The traveling wave concept enables high quality MR imaging at high magnetic field strength using wide bore magnet systems. In the conventional traveling wave approach, the RF antenna is placed outside the examination volume at the open end of the magnet bore in order to exploit the fact that the traveling waves can be generated and detected at a distance from the examined patient. However, open access to the inner bore of the magnet is obstructed in this way. According to the invention, in contrast, the RF antenna coupling to the traveling mode of the RF waveguide is either located within the examination volume in such a manner that the examination volume is freely accessible or the RF antenna is even located outside the examination volume, for example at some distance to the open end of the magnet bore such that the inner bore of the magnet is not obstructed in any way by the RF antenna.

As a consequence, the MR imaging system of the invention enables full access to the examination volume which is a substantial advantage over the conventional setup. Moreover, an improvement of the RF homogeneity can be achieved by placing the RF antenna within the examination volume according to the invention, for example by using a correspondingly optimized design of a (multi-element) RF antenna. In-bore antennas need not to be multi-element devices per se.

In comparison to the prior art, the MR imaging system of the invention provides thus more space within the magnet bore. This is advantageous for interventional applications and enables a patient-friendly design.

According to a preferred embodiment of the invention, the RF antenna is located beneath or integrated into a patient table of the MR imaging system. Optionally, the RF antenna may be located in a recess of the gradient coil of the system or an RF shield of the system or it may even be integrated into the RF shield or gradient coil of the system itself. As a consequence, in the MR imaging system according to the invention the conventional head or body RF antennas coupling to the near field of the examined body can be completely dismissed with. These conventional RF antennas, typically birdcage or TEM (transversal electromagnetic) resonators closely surround the body of the patient and thereby limit the free space within the magnet bore. An increase of the free bore diameter is achieved by placing the RF antenna for transmitting RF pulses to and/or receiving RF signals from the body of the patient in or beneath the patient table, in recesses of the RF shield or gradient coil or integrate the RF antenna even into the RF shield and/or the gradient coils. It has to be noted that the free bore diameter may even be significantly increased using a traveling wave approach and omitting a conventional volume transmitter like a quadrature body coil for magnetic field strengths beyond 3 T. The reason is that conventional (near-field) transmitters do not yield the desired homogeneous excitation at field strengths beyond 3 T.

Preferably, the at least one RF antenna of the MR imaging system according to the invention is formed by an electrically conductive plate in which at least one recess is left open. The recess may be, for example, slot-shaped. In general, a slot-line antenna may be used which may be for example realized as a slit in a metallic plate, a slitted metallic box (cavity backed slit), a slitted waveguide structure, an antenna array using a number of slits in one of the above mentioned possible designs or even a curved or arbitrarily shaped slit for generation of a desired field shape in a desired region of interest.

The electromagnetic field distribution at the edges of recesses (or slits) causes the emission of electromagnetic radiation which is coupled into the RF waveguide. A traveling wave transmit and/or receive RF antenna can be realized by an array of elongate slot-shaped recesses within the conductive plate. Such an RF antenna does not necessarily require discreet tuning capacitors. The tuning to the MR resonance frequency can be achieved by means of appropriate capacitive or low-loss dielectric loading and/or by geometrical design. The arrangement of the slot-shaped recesses within the conductive plate enables the optimization of the RF coverage and homogeneity within the examination volume. The conductive plate may for example be curved matching the curvature of the inner bore of the MR magnet system in order to optimally adapt to the MR system regarding a maximum space available in the examination volume.

It has to be noted here that the mentioned RF antenna which is formed by an electrically conductive plate in which at least one recess is left open, does not necessarily require the presence of an RF waveguide for guiding traveling RF waves along an axis of the examination volume in at least one traveling mode of the RF waveguide. By choosing appropriate spatial and electrical properties of the slot-line antenna, this antenna can be used in state of the art MR imaging systems without the presence of additional RF waveguides. Consequently, such slot-line antennas may be used to replace conventional RF antennas. However it has to be noted that also a combination with conventional RF antennas is possible.

For this reason, the invention also relates to an RF antenna for an MR imaging system wherein the RF antenna is formed by an electrically conductive plate comprising at least one recess. The invention also relates to an MR system imaging system which comprises a main magnet for generating a uniform, steady magnetic field within an examination volume, wherein the system further comprises at least one RF antenna for transmitting RF pulses to and/or receiving MR signals from a body of a patient positioned in the examination volume, wherein the RF antenna is formed by an electrically conductive plate comprising at least one recess. Further, the system comprises a control unit for controlling the temporal succession of RF pulses and a reconstruction unit for reconstructing an MR image from the received MR signals. In this case, a conventional MR imaging system being defined such that no traveling wave can propagate in its bore at the Larmor frequency may be employed. I.e. the traveling wave concept is optional in this case. Nevertheless, all concepts described throughout the description regarding an RF antenna formed by an electrically conductive plate comprising at least one recess in combination with the traveling wave approach may be used in a conventional MR imaging system being defined such that no traveling wave can propagate in its bore at the Larmor frequency.

Generally, an in bore transmit/receive slot-line resonator array may be used. Consequently, an antenna pattern may be provided which consists of an array of slot-line structures which require only very few or even no discreet tuning elements, like capacitors. The entire RF current flows over a broad distributed surface instead along discreet strips. The surface may be tuned via capacitive or low-loss dielectric loading, mechanical tuning or electrical tuning using e.g. (PIN)-diodes. A combination of these methods is also possible.

The slot-line concept can be combined with conventional near field coil elements and increases design freedom of the RF system and gradient coils. The slot-line antenna can be driven as a conventional mutual coupled volume resonator or as a multi-transmit coil array. Besides replacing the body coil in an MR system, slot-line antennas may also be used as surface (TxRx) (transmission/reception) array coils or insert volume coils, e.g. for head imaging.

This has the advantage that MR systems can be provided at lower costs. Since slot-line antennas require only a minor amount of space, this also results in more space in the bore of the MR system (i.e. in the examination volume) for example for interventional applications and patient-friendly designs.

According to a preferred embodiment of the invention, the geometry, i.e. the shape, size and/or position of the at least one recess is variable. This can be achieved for example mechanically. To this end, the conductive plate may comprise a number of plate sections that are movable relatively to each other. Alternatively, the at least one recess of the conductive plate may be bridged, as mentioned above, by one or more switchable PIN-diodes and/or one or more capacitors in order to modify the effective geometry of the recesses. This variability of the RF antenna can be used for tuning purposes as well as for the purpose of optimizing the RF field distribution within the examination volume, which is called RF shimming.

Using more than one slot forming a multi-element transmit system, the position, size and shape of the slots may be chosen such that an improved RF coverage, improved homogeneity in a given region of interest and/or improved, i.e. reduced specific absorption rate (SAR) is resulting.

In accordance with a further embodiment of the invention, the MR system further comprises a number of gradient coils for generating switched magnetic field gradients in different spatial directions within the examination volume, wherein the gradient coils comprise electrical conductors arranged on or in a curved body at least partially encompassing the examination volume, the conductive plate of the RF antenna being curved in a manner matching the curvature of the curved body, wherein the RF antenna is positioned contiguous to the curved body. In this embodiment, the gradient coils of the MR imaging system comprise electrical conductors arranged on or in a curve, for example cylindrical, body at least partially encompassing the examination volume, wherein the RF antenna is shaped corresponding to the shape of the gradient coil and is arranged contiguous to the gradient coil in order to obtain a maximum free space within the inner bore of the magnet. The RF antenna may be located, for example in a recess formed in the body of the gradient coil, as already mentioned above. An increased open access to the magnet bore is provided in this way.

Preferably, the curved gradient coil body is split (or partially split) along the axis of the examination volume. The recess in the conductive plate may be formed in this embodiment as a circumferential slot running along the gap between the split parts of the gradient coil body. An RF antenna with a dipole-like characteristic is obtained in this way, wherein the dipole axis parallels the longitudinal axis perpendicularly to the longitudinal axis of the magnet bore.

In accordance with a further embodiment of the invention, the RF antenna is tuned to an RF frequency using only non-discreet elements. This tuning may be even a static or dynamically achievable tuning, for example as mentioned above by means of mechanically movable elements which vary the size of the recess. However, in general in case the slot-line structure for a given frequency is realized without using any discreet elements like capacitors, the production costs of such a slot-line antenna are kept rather low. Further, the risk of failure of electrical elements is minimized. Changing of the antenna properties of the slot-line structure may even be achieved by varying the spatial dimensions of the structure (as mentioned above) or by providing dielectric materials to the structure. For example, the antennas may be individually loaded inside or on a dielectric material. The antenna may also be made from other materials than metal, for example from artificial magnetic conductors (AMCs) or even from carbon nanotubes.

In accordance with a further embodiment of the invention, a slot-line array structure of the antenna may be combined with local surface receive coils. Also a combination with transmit or receive coils tuned at lower frequencies is possible, wherein one coil may be for example used for fluorine MR imaging and the other coil may be used for proton MR imaging. Further, slot-line antennas, dipole antennas, TEM antennas, patch antennas and loop elements may be mixed in a suitable manner in order to obtain optimized RF transmission or reception capabilities of the MR system. This may be combined with multi-resonance excitation patterns, active slit length tuning using PIN-diodes for active shimming and further, as mentioned above, RF shimming by variable dielectric loading of the cylindrical bore.

In accordance with a further embodiment of the invention, the RF antenna is a directional antenna, wherein the directional antenna comprises directional antenna characteristics directed towards the examination volume.

While a conventional (body-) coil couples to the reactive near field of the sample and is thus loaded by sample losses, a propagation wave excitation antenna couples to a mode of the cylindrical waveguide of the MR system. While conventional MR coils are operated in the near field regime inside a cylindrical conducting bore at ultra-high magnetic fields, the cylinder itself acts as a waveguide as soon as the MR frequency is below the cut-off frequency of the waveguide. The electromagnetic energy is then transported through the cylinder by a traveling wave. The cut-off frequency of a given cylindrical bore can be considerably lowered by a dielectrical loading.

In order to realize traveling wave excitation in a bore, which initially does not allow wave propagation, dielectric filling with material of high permittivity on the surface of the cylinder or partly below the patient support may be applied. The presence of the patient body further reduces the cut-off frequency due to the additional dielectric loading effect. By using a directional RF antenna which is located on the imaging system such that the examination volume is freely accessible, for example outside the MR bore comprising the examination volume, a traveling wave is excited inside the examination volume of the MR system.

Having an antenna gain substantially larger than one in the direction of the main beam, also an array of directional antennas may be used to lower the RF amplifier power needed for a given B₁ field in the bore. Moreover, the directional antenna characteristics allows for tailoring the excitation conditions of such MRI systems.

Furthermore, such an antenna system may also be integrated into the bore or placed at the edges of the magnet. Antenna elements may for example be located at the service end of the scanner still allowing free access to the bore. This may provide a significant gain in the bore diameter while keeping the system compact.

In accordance with a further embodiment of the invention, the RF antenna comprises a periodic antenna structure providing said antenna characteristics directed towards the examination volume.

In accordance with an embodiment of the invention, the MR system may comprise a phased array of RF antennas which has the advantage of providing optimized transmission and reception capabilities by such antennas. Consequently, an excitation field in the examination volume may be formed by external antenna design.

In accordance with a further embodiment of the invention, the RF antenna is a Yagi type antenna or a helically structured antenna. Further, the antenna may be a dipole and/or quarter wave line structured antenna.

A further advantage of such directional antennas is that these antennas comprise a simpler and less expensive antenna structure even without any capacitors. The antenna size may be adapted in a desired manner by individually loading the antennas for example inside or on a dielectric material. It has to be noted that a combination of a traveling wave antenna setup with conventional RF antennas is possible in order to achieve a combination of traveling/propagating mode excitation and conventional near field excitation. For example, in a phase locked mode the traveling mode antennas may be used for ‘base’ polarization purposes and local antennas like for example TEM or strip-line antennas may be used for additional purposes like for example RF shimming. Furthermore, RF shimming is possible by variable dielectric loading of the cylindrical bore.

In accordance with a further embodiment of the invention, resonant passive antenna structures may be used close to the examination volume in order to facilitate traveling wave propagation. For example slots or dipoles may be used in the patient table as resonant structures in order to provide a locally enhanced B₁ which permits reducing the power required for driving the traveling wave antenna setup.

In accordance with a further embodiment of the invention, the traveling wave antennas may be hidden under the cover of the MR magnet or even may be integrated into the gradient coils of the MR system.

In accordance with a further embodiment of the invention, the RF room enclosing the MR magnet, as well as the MR magnet itself has RF absorbing properties in order to avoid unwanted reflections of RF waves in case the RF antenna is located outside the examination volume and even outside the MR magnet itself.

External traveling wave antennas may be driven with amplifiers located on or near the antennas themselves, allowing for the construction of compact antenna setups.

According to yet another preferred embodiment of the invention, the RF waveguide is formed by an open-ended tube surrounding the examination volume. The tube defines the magnet bore of the MR imaging system. The tube may have a circular or elliptical shape. The tube acts as a waveguide provided that the MR frequency is beyond a cut-off frequency determined by the dimensions of the tube. This may be the case at high magnetic field strength and large inner bore diameters. The electromagnetic energy of the RF fields generated within the bore is then transported through the tube by traveling waves. For example, an electrically conductive screen or mesh lining the inner bore of the magnet may be used as a waveguide according to the invention.

The tube may comprise an electrically conductive pattern structure so as to enable guiding of the traveling RF waves in a selected traveling mode. The electrically conductive pattern determines the current path within the waveguide. The propagation of undesirable higher order modes can be suppressed in this way.

According to still a further preferred embodiment of the invention, the MR imaging system comprises at least one surface antenna located within the examination volume for receiving MR signals from a limited region of the body. In this way, traveling wave RF excitation can be combined with local detection of MR signals, for example by means of an array of conventional (tunable) RF surface coils coupling to the near field of the examined body. This hybrid approach provides additional degrees of freedom in the design of the RF system of the MR imaging apparatus and advantageously combines the improved RF coverage and homogeneity of traveling wave excitation with the high sensitivity of close range detection via RF surface antennas.

It has to be mentioned, that both, the slot-line structured antenna as well as the traveling wave antenna may be used for either RF excitation purposes, receiving MR signals after excitation or a combination thereof.

### BRIEF DESCRIPTION OF THE DRAWINGS

The enclosed drawings disclose preferred embodiments of the present invention. It should be understood however, that the drawings are designed for the purpose of illustration only and not as a definition of the limits of the invention.

In the drawings:

FIG. 1 shows schematically an MR imaging system according to the invention;

FIG. 2 shows a sketch of a slot-type RF antenna positioned in the examination volume of an MR imaging system below a patient;

FIG. 3 illustrates an individual RF antenna according to the invention;

FIG. 4 shows a planar array of slots forming an RF antenna according to the invention;

FIG. 5 shows a planar slot-line antenna with feed;

FIG. 6 illustrates an RF chain connected to a slot-line antenna;

FIG. 7 shows a slitted metal plate carrying a slot-line antenna;

FIG. 8 shows an array of slot-line antennas;

FIG. 9 shows a slot-line antenna in combination with dielectric material;

FIG. 10 illustrates different detuning strategies for a slot-line antenna;

FIG. 11 illustrates slot-line antennas in an MR system with split gradient coil;

FIG. 12 illustrates slot-line antennas in an MR system with a recess in the gradient coil;

FIG. 13 depicts a longitudinal cut through an MR imaging system according to the invention;

FIG. 14 shows an external Yagi antenna;

FIG. 15 depicts a planar directional antenna on a dielectric layer;

FIG. 16 illustrates different patterns of individual elements of a directional antenna structure;

FIG. 17 illustrates a helical antenna design;

FIG. 18 illustrates a directional antenna for producing a circular field;

FIG. 19 illustrates a combination of a directional antenna and a traveling wave structure;

FIG. 20 illustrates the combination of several individual directional antennas.

### DETAILED DESCRIPTION OF EMBODIMENTS

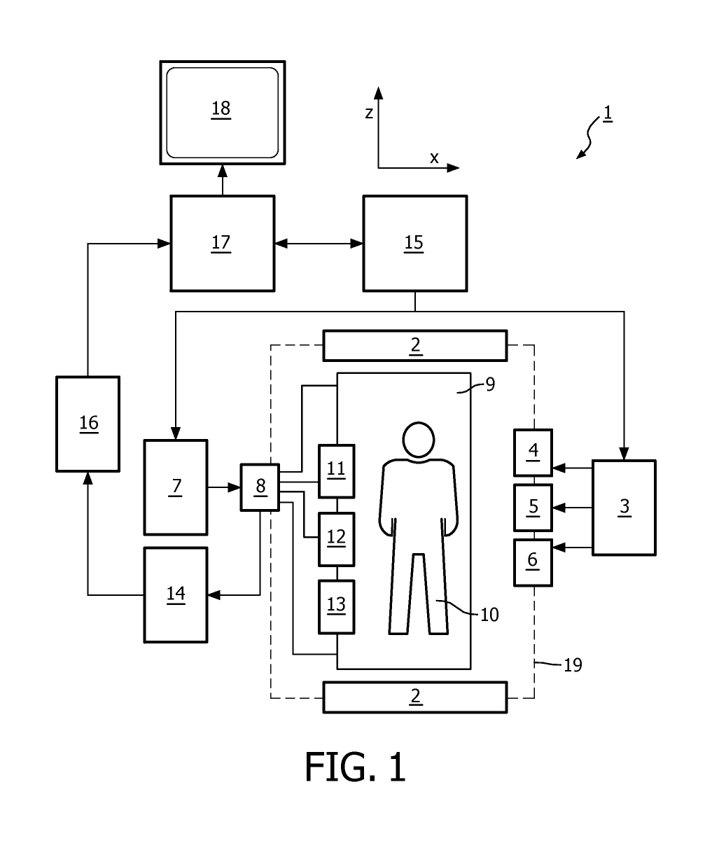

With reference to FIG. 1, an MR imaging system 1 is shown. The system comprises superconducting or resistive main magnet coils 2 such that a substantially uniform, temporally constant main magnetic field is created along a z-axis through an examination volume.

A magnetic resonance generation and manipulation system applies a series of RF pulses and switched magnetic field gradients to invert or excite nuclear magnetic spins, induce magnetic resonance, refocus magnetic resonance, manipulate magnetic resonance, spatially or otherwise encode the magnetic resonance, saturate spins and the like to perform MR imaging.

More specifically, a gradient pulse amplifier 3 applies current pulses to select ones of whole body gradient coils 4, 5 and 6 along x, y and z-axis of the examination volume. An RF transmitter 7 transmits RF pulses or pulse packets, via a send/receive switch 8, to an RF antenna 9 to transmit RF pulses into the examination volume. A typical MR imaging sequence is composed of a packet of RF pulse sequences of short duration which taken together with each other and any applied magnetic field gradients achieve a selected manipulation of nuclear magnetic resonance. The RF pulses are used to saturate, excite resonance, invert magnetization, refocus resonance, or manipulate resonance and select a portion of a body 10 positioned in the examination volume. The MR signals may also be picked up by the RF antenna 9.

For generation of MR images of limited regions of the body 10, for example by means of parallel imaging, a set of local array RF coils 11, 12 and 13 are placed contiguous to the region selected for imaging. The array coils 11, 12 and 13 can be used to receive MR signals induced by RF transmissions effected via the RF antenna. However, it is also possible to use the array coils 11, 12 and 13 to transmit RF signals to the examination volume.

The resultant MR signals are picked up by the RF antenna 9 and/or by the array of RF coils 11, 12 and 13 and are demodulated by a receiver 14 preferably including a preamplifier (not shown). The receiver 14 is connected to the RF coils 9, 11, 12 and 13 via a send/receive switch 8.

A host computer 15 controls the gradient pulse amplifier 3 and the transmitter 7 to generate any of a plurality of imaging sequences, such as echo planar imaging (EPI), echo volume imaging, gradient and spin echo imaging, fast spin echo imaging and the like. For the selected sequence, the receiver 14 receives a single or a plurality of MR data lines in rapid succession following each RF excitation pulse. A data acquisition system 16 performs analogue to digital conversion of the received signals and converts each MR data line to a digital format suitable for further processing. In modern MR devices the data acquisition system 16 is a separate computer which is specialized in acquisition of raw image data.

Ultimately, the digital raw image data is reconstructed into an image representation by a reconstruction processor 17 which applies a Fourier transform or other appropriate reconstruction algorithms. The MR image may represent a planar slice through the patient, an array of parallel planar slices, a three-dimensional volume, or the like. The image is then stored in an image memory where it may be accessed for converting slices, protections or other portions of the image representation into appropriate formats for visualization, for example via a video monitor 18, which provides a man-readable display of the resultant MR image.

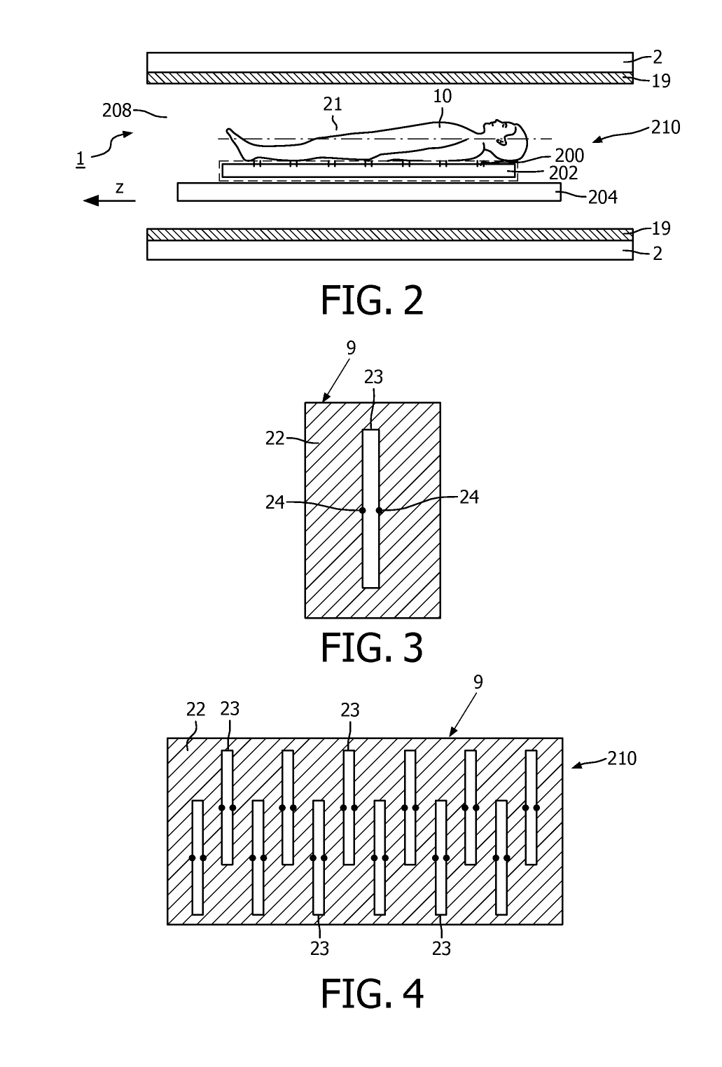

Also shown in FIG. 1 is an RF waveguide 19 which in the following shall be explained in further detail with respect to FIG. 2.

FIG. 2 shows a sketch of a slot-type RF antenna positioned in the examination volume of the MR imaging system 1 below the patient 10. In the embodiment shown in FIG. 2, the MR imaging system 1 of FIG. 1 additionally comprises the RF waveguide 19 for guiding traveling RF waves along the z-axis of the examination volume in at least one traveling mode of the RF waveguide 19. The RF waveguide 19 may be formed by the structures surrounding the body 10, such as the gradient coils 4, 5 or 6, the walls of the cryostats of the main magnet coils 2 and RF screens (not shown). Alternatively, the RF waveguide 19 may be a separately provided open-ended tube of circular, elliptical, rectangular or tapered cross-section, surrounding the examination volume, as depicted with reference numeral 19 in FIG. 2. An electrically conductive screen or mesh lining the inner wall of the magnet may be used as an RF waveguide 19. Provided that the MR frequency is beyond a cut-off frequency determined by the dimensions of the RF waveguide 19, the electromagnetic energy of the RF fields generated via the RF antenna 9 within the bore is transported through the waveguide 19 by traveling waves.

With further reference to FIG. 2, the RF antenna 9 of FIG. 1 is located beneath a patient table 202 of the MR imaging system. The patient table 202 itself is located movable on a bridge 204 of the MR imaging system 1. The tube-shaped RF waveguide 19 defines the inner bore of the magnet, i.e. the free space constituting the examination volume 21 of the MR imaging system 1. As can be seen in FIG. 2, the maximum free bore diameter is achieved by placing the RF antenna for transmitting RF pulses and/or receiving MR signals from the body 10 beneath the patient table 202. In the embodiment shown in FIG. 2, the RF antenna 9 is formed by a slot-line antenna 200.

Consequently, the RF antenna 9 is located on the imaging system such that the examination volume 21 is freely accessible.

This has the advantage that the examination volume and thus the patient 10 is freely accessible from both, the left side 208 and the right side 210 of the MR system 1, wherein the left and right side 208 and 210 are defined in FIG. 2 with respect to a longitudinal cut through the MR system along the z-axis.

Again, it has to be mentioned that the slot-line antenna 200 may also be applied and used without the presence of the RF waveguide 19. The waveguide is thus optional in this embodiment.

An embodiment of the slot structure 200 (see also FIG. 4) shall be discussed in more detail in the following with respect to FIG. 3 which illustrates an individual RF antenna 9 formed by a slot-line antenna 200. The slot-line antenna 200 comprises as an individual element an electrically conductive plate 22 in which slot-shaped recesses 23 are left open. The electromagnetic field distribution at the edges of the recesses 23 causes the emission of electromagnetic radiation which may be coupled into the (optional) RF waveguide 19 (see FIG. 2). Depending on the mode selected for traveling wave excitation, the recesses may be arranged perpendicularly to the z-axis of the MR imaging system 1. The recesses 23 may also be of a curved shape or any other geometry adapted to optimize the RF field distribution within the examination volume 21. In the embodiment depicted in FIG. 3, one or more feed points 24 for connecting the RF antenna 9 via the send/receive switch 8 to the RF transmitter 7 (see FIG. 1) are positioned at the center between the slot-shaped recesses 23.

The antenna element depicted in FIG. 3 is an individual RF antenna element comprising a single slot 23. The feed points 24 are arranged at the opposing edges of the slot 23 for symmetrical balanced excitation. The output of RF power MOSFET used as RF transmitter 7 (see FIG. 1) may be connected directly to the feed points 24 in order to obtain low impedance excitation of the RF antenna 9.

FIG. 4 shows a planar array 200 of slots 23 forming an RF antenna 9 according to the invention. In this embodiment, the traveling wave transmit and/or receive RF antenna 9 is realized by an array of elongate slot-shaped recesses 23 within the conductive plate 22. Such an RF antenna preferably does not require discreet tuning capacitors. The tuning of the MR resonance frequency can be achieved simply by means of appropriate capacitive or low-loss dielectric loading (not shown). However, in general tuning of the slot-line antenna may be realized by mechanical and/or electrical variation of the slit length and/or width. The arrangement of the slot-shaped recesses 23 on the conductive plate 22 enables the optimization of the RF coverage and homogeneity within the examination volume 21 (see FIG. 2). The conductive plate 22 may be curved matching the curvature of the inner bore of the MR imaging system. However, in general the geometry of the RF antenna 9 can be adapted in any way in order to enable integration into the gradient coil arrangement surrounding the examination volume 21 of the MR imaging apparatus. Further, as already discussed with respect to FIG. 2, the geometry of the RF antenna may be adapted in order to enable integration into the patient table 202.

It has to be noted again, that the geometry of the RF antenna 9 is adapted in such a manner that the examination volume 21 is freely accessible and not blocked by the RF antenna 9 in order to gain free access to the examination volume and thus to the patient 10.

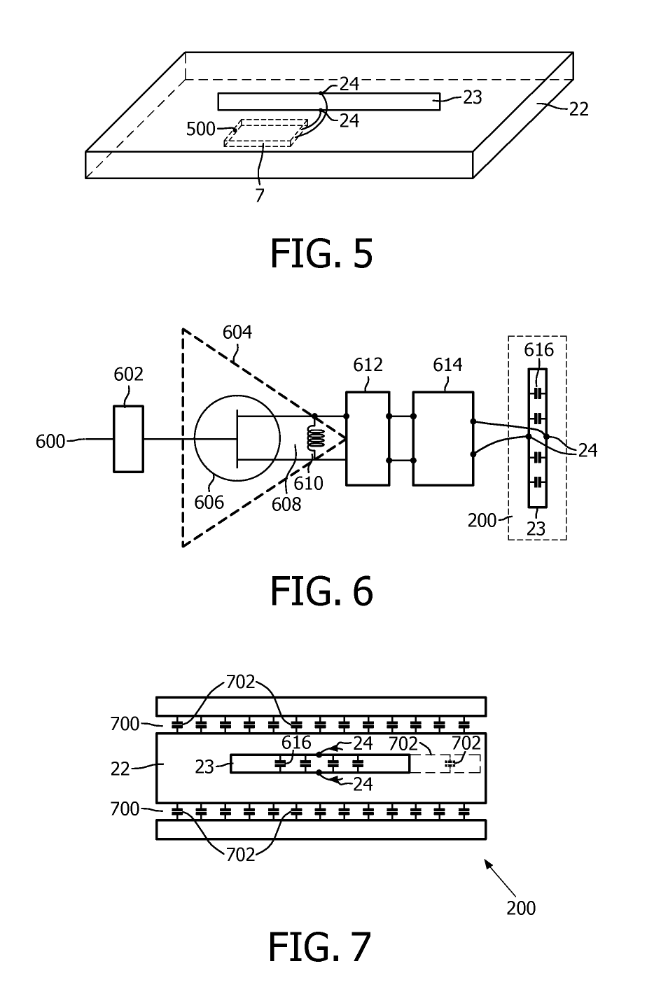

FIG. 5 illustrates a planar slot-line antenna with feed from an RF module 7 containing e.g. a power amplifier, a send/receive-switch, a preamplifier and/or a digital optical connection and or a wired connection 500 to the driving electronics. Again, the input feed is connected to the feed points 24 center of the slot 23. The RF module is preferably located near or even within the antenna, i.e. mounted for example on the conductive plate 22 of the RF antenna 9 on which the slot-shaped recess 23 is left open. The RF module 7 may comprise for example an analogue or digital input and/or output 500 in order to send/receive respective signals to and from the RF module 7. The digital or analogue signals may be communicated via the input/output 500 with the host computer 15 discussed with respect to FIG. 1.

FIG. 6 illustrates an RF chain connected to a slot-line antenna 200. The RF chain comprises an input 600 and an amplifier 604, which may for example comprise a field effect transistor 606 in order to amplify the signals received via the input 600. The slot-line antenna 200 comprises an impedance which may be matched to the impedance of the amplifier 604 using a suitable network of lumped elements or a cable transformation or both. For example, matching may be performed by means of a capacitance 608 of the field effect transistor 606 and/or an impedance 610 of a respective coil element within the amplifier 604. One or several baluns 602 and 612 may be introduced for suppressing common modes on the cabling. Further, an additional matching circuit 614 may be used in order to match the antenna impedance to the impedance of the amplifier 604. The balun 612 is used in order to symmetrize the signal amplified by the FET 606 since typically the amplified signal is non-symmetric, whereas the slot 23 is symmetric. While FIG. 6 shows an arrangement matching the slot-impedance to a power amplifier driving the antenna in transmission, an appropriate low noise arrangement for the case of signal reception with the slot-antenna can be thought of and is not shown here. Essentially the signal picked up by the antenna is fed to the input of a low noise FET using an appropriate matching network of lumped elements or suitable cable providing the desired transformation.

As can be further seen in FIG. 6, the slot-line antenna 200 comprises a slot 23 which is bridged with capacitors 616. This shall be described in greater detail with respect to FIG. 7.

FIG. 7 illustrates a slitted metal plate carrying a slot-line antenna. The antenna comprises again the slot-shaped recess 23 with the respective feed points arranged at the opposing edges of the slot for symmetrical balanced excitation. In the embodiment shown in FIG. 7, the recess 23 is bridged with capacitors 616 for optimized tuning of the slot-line antenna 200.

In FIG. 7, the slot-line antenna 200 further comprises eddy current barriers comprising slits 700 which are bridged by further capacitors 702. Switching gradient fields typically induce Eddy currents in the conducting structures 22 of the slot-line antenna according to the Faraday's law of induction. These Eddy currents may distort the magnetic field generated within the magnet bore and thus cause distortions of the MR image to be reconstructions. By means of the Eddy current barrier formed by the slots 700 and the capacitors 702, gradient induced eddy currents are prevented from propagation.

This principle can also be applied to the recess 23 which may be extended in length, as indicated by the dashed lines 704. By bridging this extended part 704 of the recess 23 by further appropriate capacitors 706, this part 704 can be made non-resonant thus also acting as Eddy current barrier. Consequently, only the recess 23 is resonant in a desired manner.

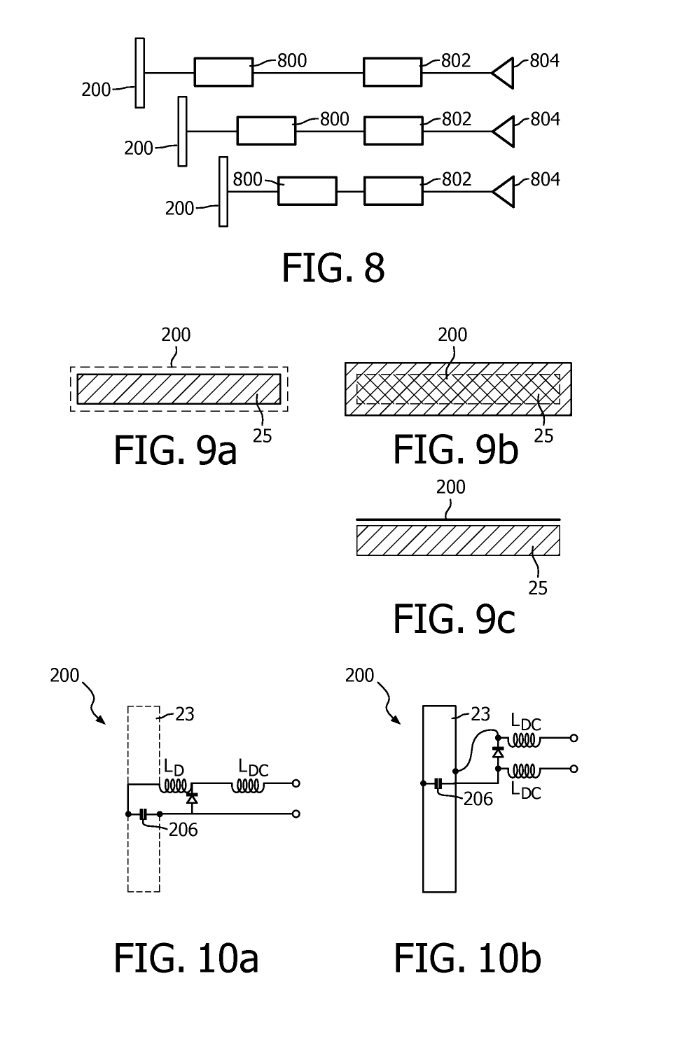

FIG. 8 illustrates an array of slot-line antennas 200, each equipped with a separate balun 800 and matching circuit 802, as well as a respective power amplifier 804. Such an array provides multi-element transmit/receive capabilities. This may be either used in combination with state of the art parallel imaging techniques and/or multi-antenna element excitation RF field provision to the examination volume 21 of the MR imaging apparatus 1. The combination of several individual slot antennas may be used for example in transmission mode in order to optimize the formation of the excitation field to the object 10 to be imaged.

FIG. 9 illustrates various embodiments of a slot-line antenna structure 200 in combination with a dielectric material 25. In FIG. 9a, the slot-line antenna 200 is filled with the dielectric material 25. In FIG. 9b, the slot-line structure is embodied in the dielectric material 25 and in FIG. 9c the slot-line structure 200 is placed upon the surface of the dielectric material 25. The combination of the slot-line structure 200 and the dielectric material 25 may be performed in order for optimized tuning and/or matching purposes.

FIG. 10 illustrates different detuning strategies for a slot-line antenna 200. Detuning may be used when for example using the slot-line antenna 200 for the purpose of RF transmission only or for the purpose of RF reception only. In FIG. 10a, an inductor may be switched in parallel to the tuning capacitor 19 of the slot 23. Alternatively, as shown in FIG. 10b, the tuning capacitor 19 may be shortened by means of an inductor. The DC wires providing the diode bias may be trapped using RF-chokes.

It has to be mentioned that in case multiple slot-line antennas are used for providing multi-element transmit/receive capabilities, a decoupling network between the individual antennas may be inserted realizing a suitable impedance between recesses of individual slot-line antennas. Alternatively, inductive decoupling may also be used for this purpose.

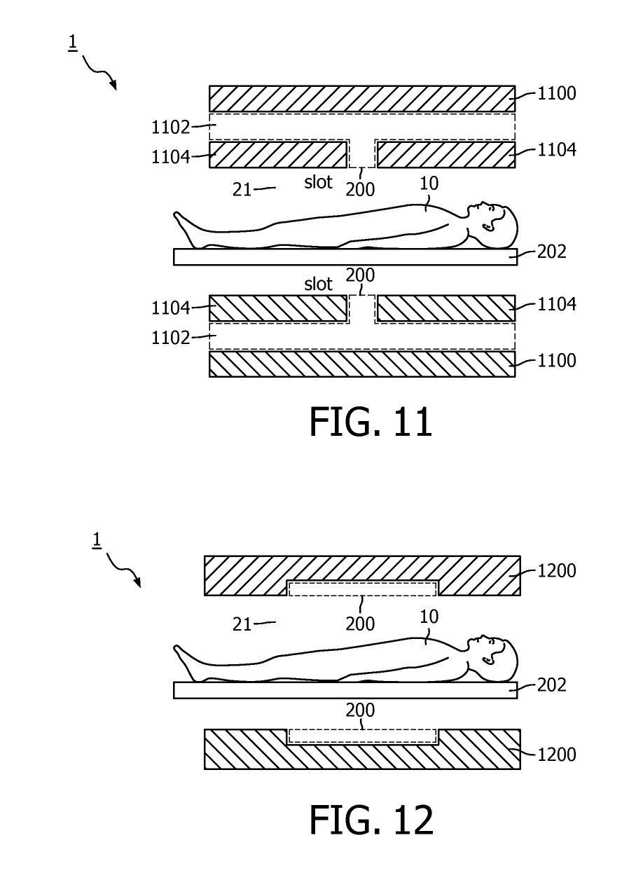

FIG. 11 illustrates slot-line antennas in an MR system with split gradient coils. The MR system 1 illustrated in FIG. 11 comprises tube-shaped gradient coils 1100 and 1104, wherein FIG. 11 illustrates only a longitudinal cross-section of said gradient coils. The MR system further comprises an RF shield 1102 which is located between the gradient coils 1100 and 1104. The gradient coil 1104 is a split gradient coil comprising two halves, wherein in between these two halves a recess is formed. The recess is filled with one or more antennas mounted in between the two halves of the gradient coil 1104 freeing inner bore diameter from the presence of RF antennas.

An alternative embodiment is shown with respect to FIG. 12 which illustrates slot-line antennas 200 in an MR system with a recess in the gradient coil 1200. As a consequence, the examination volume 21 is freely accessible thus permitting access to the patient 10 who is located within the examination volume 21 on the patient table 202 from both sides of the cylindrical MR magnet system. Additionally, the inner bore with the examination volume 21 is freed thus providing more space with respect to the examination volume 21.

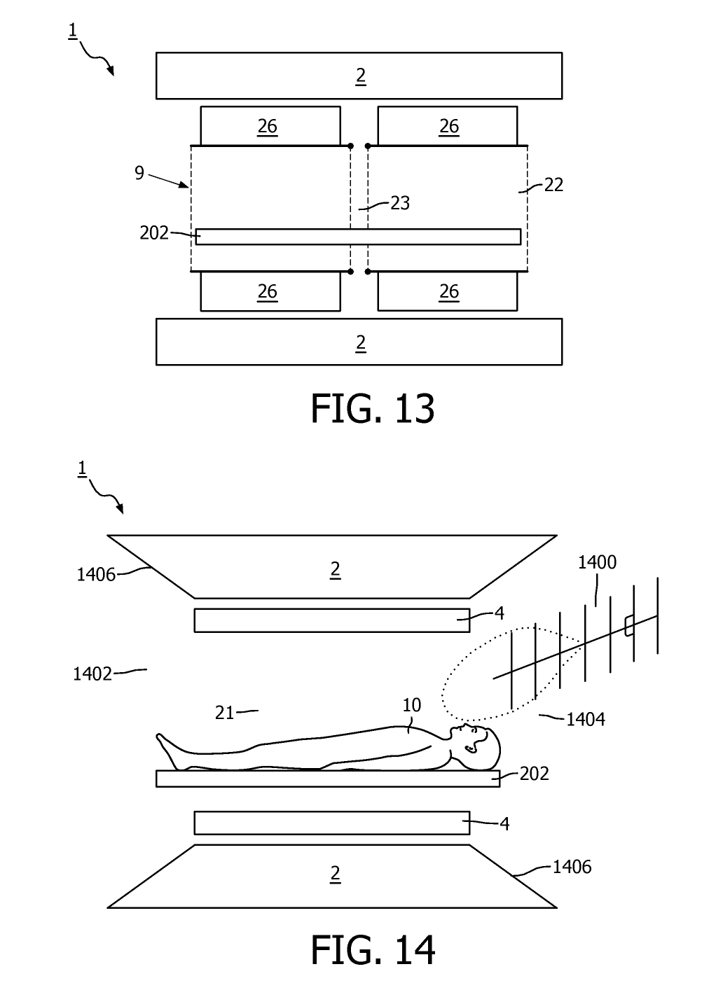

FIG. 13 depicts a longitudinal cut through an MR imaging system 1 according to the invention. The system comprises superconducting or resistive main magnet coils 2 (see FIG. 1). Further, the gradient coils 4, 5 and 6 of the MR imaging system 1 (see FIG. 1) comprise electrical conductors (not shown) arranged on or in a cylindrical body 26 surrounding the examination volume 21 in which the patient table 202 is located. The conductive plate 22 of the RF antenna 9 is curved in a manner matching the curvature of the cylindrical body 26. The RF antenna 9 is shaped correspondingly to the shape of the gradient coil body 26 and is arranged directly contiguous to the gradient coil body 26 such that again a maximum free space is obtained within the inner bore of the magnet. Similarly as discussed above with respect to FIG. 11, the cylindrical gradient coil body 26 is split here along the longitudinal axis (z-axis) of the examination volume 21. The recess 23 in the conductive plate 22 is formed as a circumferential slot running along the gap between the split parts of the gradient coil body 26.

It has to be noted that any of the above mentioned slot-line array structures and incorporations in the MR system may be combined with local surface receive coils as known in the art.

FIG. 14 illustrates a further embodiment of an MR imaging system 1 in which instead of a slot-line antenna a directional antenna 1400 is used. The directional antenna 1400 comprises directional antenna characteristics directed towards the examination volume 21. The directional antenna 1400 hereby corresponds to the RF antenna 9 in FIG. 1. The directional antenna 1400 may comprise a built-in RF module comprising again for example a power amplifier for transmission, a pre-amplifier for reception, a transmission/receive switch, an analogue-to-digital converter or any other kind of RF module components. Preferably, such an RF module is again located near or even on the antenna 1400.

As can be seen from FIG. 14, the directional antenna 1400 is located outside the examination volume 21 and even outside of the cylindrical magnet system 2 and the gradient system 4. Due to the directional characteristics of the antenna 1400, the antenna is not physically blocking the open ends 1402 or 1404 of the cylindrical magnet system 2. Consequently, the examination volume 21 is again freely accessible.

In accordance with a further embodiment of the invention, the open ends of the magnet are inclined, wherein the antenna 1400 may be comprised on the surface 1406 of the inclined parts of the magnet 2. Again, the antenna 1400 is not blocking the open ends 1402 or 1404 of the magnet 2 thus permitting a free access to the examination volume 21.

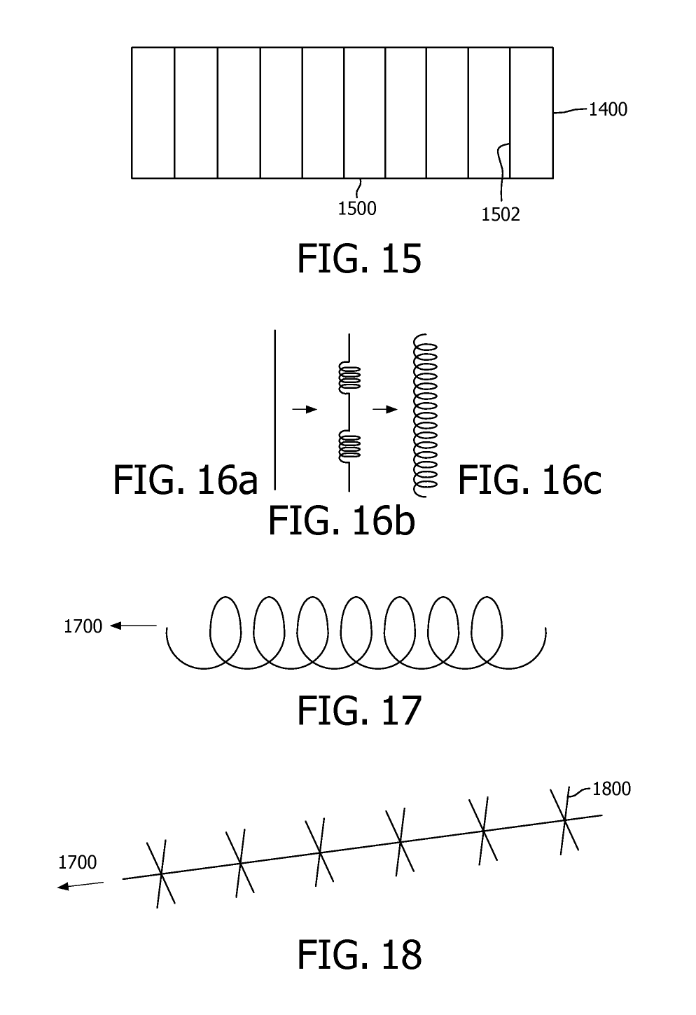

FIG. 15 illustrates a directional antenna 1400 which consists of a metallic array structure 1502 on a support 1500. In an embodiment of the invention, the support 1500 may be or comprise a dielectric layer which permits to shorten the electrical length and size of the antenna. Consequently, the antenna is located inside or on a dielectric material. Generally, the directional antenna should be designed in a manner to show a gain larger than 1 in the direction of the main beam allowing for a spatial selective application of the excitation energy to various areas of the examination volume 21. It has to be pointed out that the directional antenna 1400 may preferably be used in combination with a waveguide in the inner bore of the magnet—a waveguide in the inner bore of the magnet may especially be suitable in case a rather homogenous RF field distribution in the examination volume 21 is desired.

The antennas 1400 depicted in FIGS. 14 and 15 are for example so-called Yagi antennas. However, any kind of suitable directional antenna may be used. Different patterns of individual elements of respective antenna structures may be applied. For example FIG. 16 illustrates different patterns of individual elements of a Yagi structure. In FIG. 16a, the dipoles of a Yagi antenna are straight conductors, wherein in FIG. 16b parts of the dipoles of the antenna structure are arranged in a spiral manner. In FIG. 16c, a dipole of an antenna structure is completely arranged in a spiral manner. Consequently, the width of such a Yagi type antenna, i.e. the length of the antenna in the direction of the dipole orientation, is shortened in FIGS. 16b and 16c compared to FIG. 16a.

In FIG. 17, a helical antenna design is shown, wherein the antenna characteristics are directed towards direction 1700. Not shown in FIG. 17 is a respective reflecting mirror which may be required at one end of the helical antenna structure.

FIG. 18 illustrates a Yagi antenna producing an RF field with a circularly or elliptically polarized excitation. Such an antenna design has the advantage that by means of crossed dipoles 1800 and an individual control of the RF power provided to each dipole of the crossed dipoles 1800, the excitation in direction 1700 can be controlled in a highly precise manner. For example it is possible to rotate the direction of polarized excitation individually under control of the host computer 15 (FIG. 1). Consequently, the excitation within the examination volume 21 of the MR system 1 (FIG. 1) can be controlled in a highly precise and desired manner.

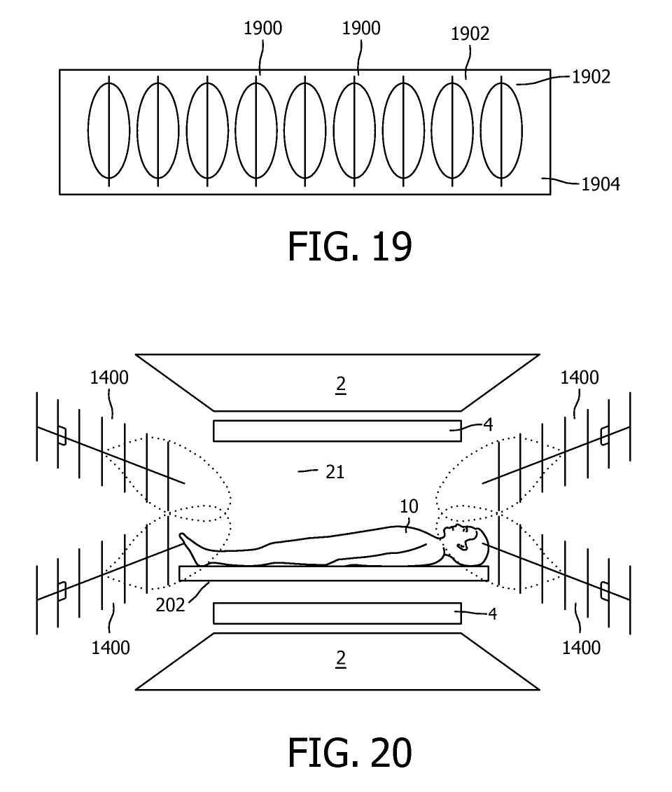

FIG. 19 shows the combination of a Yagi antenna 1900 and a circular traveling wave structure 1902. Both, the Yagi antenna and the traveling wave structure may be comprised on a dielectric layer and support 1904 to shorten again the length of the respective antenna elements. It has to be noted, that instead of inductively coupling circular loops (or elliptical loops) also a birdcage coil structure may be used as a traveling wave structure.

FIG. 20 illustrates the combination of several individual directional antennas, for example Yagi antennas. The individual antennas 1400 may either be used for RF signal transmission and/or reception purposes. By employing multiple individual directional antennas 1400, for example for the purpose of MR excitation the individual antennas may provide the RF signals at different amplitudes or phases thus yielding in combination an optimized excitation. Consequently, the excitation field in the examination volume 21 can be formed under control of the host computer 15 from outside the magnet without the need of time consuming manual spatial repositioning of the antennas 1400.

1. A magnetic resonance imaging system comprising:
a main magnet for generating a uniform, steady magnetic field within an examination volume,
an RF waveguide for guiding travelling RF waves along an axis of the examination volume in at least one travelling mode of the RF waveguide,
at least one RF antenna for transmitting RF pulses to and/or receiving MR signals from a body of a patient positioned in the examination volume, wherein the RF antenna is configured to couple to the at least one travelling mode of the RF waveguide, and wherein the RF antenna is located on the imaging system such that the examination volume is freely accessible,
a control unit for controlling the temporal succession of RF pulses, and
a reconstruction unit for reconstructing an MR image from the received MR signals.

2. The MR imaging system according to claim 1, wherein the RF antenna is located beneath or integrated into a patient table, on which the body of the patient is positioned.

3. The MR imaging system according to claim 1, wherein the RF antenna is formed by an electrically conductive plate having at least one recess.

4. The MR imaging system according to claim 3, wherein the shape, size and/or position of the recess is mechanically variable.

5. The MR imaging system according to claim 3, wherein the at least one recess of the conductive plate is bridged by one or more PIN diodes and/or one or more capacitors.

6. The MR imaging system according to claim 3, wherein the system further comprises a number of gradient coils for generating switched magnetic field gradients in different spatial directions within the examination volume, wherein the gradient coils comprise electrical conductors arranged on or in a curved body at least partially encompassing the examination volume, the conductive plate of the RF antenna being curved in a manner matching the curvature of the curved body, wherein the RF antenna is positioned contiguous to the curved body.

7. The MR imaging system according to claim 6, wherein the curved body is split along the axis of the examination volume.

8. The MR imaging system according to claim 3, wherein the RF antenna is tuned to an RF frequency using only non-discrete elements.

9. The MR imaging system according to claim 1, wherein the RF antenna is a directional antenna, wherein the directional antenna comprises directional antenna characteristics directed (towards the examination volume.

10. The MR system according to claim 9, wherein the RF antenna is located outside the examination volume.

11. The MR system according to claim 9, wherein the RF antenna comprises a periodic antenna structure providing said antenna characteristics directed towards the examination volume.

12. The MR system according to claim 9, wherein the MR system comprises a phased array of RF antennas.

13. The MR imaging system according to claim 1, wherein the RF waveguide is formed by an open-ended tube surrounding the examination volume.

14. The MR imaging system according to claim 13, wherein the tube comprises an electrically conductive pattern structured so as to enable guiding of travelling RF waves in a selected travelling mode.

15. An RF antenna for an MR imaging system, wherein the RF antenna is formed by an electrically conductive plate comprising at least one recess.
